(19) United States
(12) Patent Application Publication
(10) Pub. No.: US 2019/0356291 A1
(43) Pub. Date: Nov. 21, 2019

(54) PARAMETER SETTING DEVICE AND PARAMETER SETTING METHOD

(71) Applicant: YAMAHA CORPORATION, Hamamatsu-shi (JP)

(72) Inventors: Kosuke SAITO, Hamamatsu-shi (JP); Masaaki OKABAYASHI, Hamamatsu-shi (JP)

(21) Appl. No.: 16/398,391

(22) Filed: Apr. 30, 2019

(30) Foreign Application Priority Data
May 21, 2018 (JP) 2018-096938

(51) Int. Cl. H03G 3/14; H04R 3/00

(52) U.S. Cl. CPC H03G 3/14; H04R 3/00

(57) ABSTRACT

A parameter setting device includes an operator, a scale, a receptor, and a controller. The operator receives parameter changing operation from a user. The scale indicates a reference position of the operator. The receptor receives instructions of turning on a calibration mode. The controller moves the operator to the reference position, when receiving the instructions of turning on the calibration mode.

### CROSS REFERENCE TO RELATED APPLICATIONS

This Nonprovisional application claims priority under 35 U.S.C. § 119(a) on Patent Application No. 2018-096938 filed in Japan on May 21, 2018 the entire contents of which are hereby incorporated by reference.

### BACKGROUND

### 1. Field of the Invention

One exemplary embodiment of the invention relates to a parameter setting device for setting a parameter, and a parameter setting method.

### 2. Description of the Related Art

Unexamined Japanese Patent Publication No. 2011-114466 (hereinafter referred to as Patent Literature 1), International Publication No. 2008/126128 (hereinafter referred to as Patent Literature 2), and Unexamined Japanese Patent Publication No. 2008-199259 (hereinafter referred to as Patent Literature 3) disclose a parameter control device used for processing an audio signal, or the like. In the parameter control device or the like of Patent Literatures 1 to 3, depending on a position of an operator used for setting a parameter, a scale indicating the position of the operator is changed in magnification ratio or resolution curve when a fader is adjusted. Unexamined Japanese Patent Publication No. H03-58350 (hereinafter referred to as Patent Literature 4) discloses a parameter control device that aligns operators at a center position once when a fader is adjusted.

### SUMMARY

In Patent Literatures 1 to 4, there is no parameter control device that moves a fader to a reference position before the fader is adjusted. Accordingly, one exemplary embodiment of the invention aims to provide a parameter setting device that improves user's operation feeling in a calibration mode, and a parameter setting method.

A parameter setting device in accordance with one exemplary embodiment of the invention includes an operator, a scale, a receptor, and a controller. The operator receives parameter changing operation from a user. The scale indicates a reference position of the operator. The receptor receives instructions of turning on a calibration mode. When receiving the instructions of turning on the calibration mode, the controller moves the operator to the reference position.

According to one exemplary embodiment of the invention, user's operation feeling in the calibration mode can be improved.

The above and other elements, features, characteristics, and advantages of the present invention will become more apparent from the following detailed description of the preferred embodiments with reference to the attached drawings.

### BRIEF DESCRIPTION OF THE DRAWINGS

FIG. 1 is a block diagram showing a configuration of a parameter setting device 1 in accordance with a first exemplary embodiment;

FIG. 2 is a view exemplarily showing an operator 10 in the parameter setting device 1;

FIG. 3 is a view exemplarily showing the operator 10 in the parameter setting device 1;

FIG. 4 is a flowchart showing an operation of the parameter setting device 1 in accordance with the first exemplary embodiment;

FIG. 5 is a block diagram showing a configuration of a mixer 4 in accordance with a second exemplary embodiment;

FIG. 6 is an equivalent block diagram of signal processing performed in a signal processor 44, an audio I/O43, and a CPU48;

FIG. 7 is a view showing a block configuration of an input channel i;

FIG. 8 is a view showing an operation panel of the mixer 4 in accordance with the second exemplary embodiment;

FIG. 9 is a flowchart showing an operation of the mixer 4 when a user operates an ON-button 602 in the operation panel;

FIG. 10 is a view exemplarily showing an operation panel of the mixer 4 displayed when a calibration mode is turned on;

FIG. 11 is a flowchart showing an operation of the mixer 4 when a user operates a fader 601;

FIG. 12 is a view exemplarily showing an operation panel of the mixer 4 displayed when a calibration mode is turned on;

FIG. 13 is a flowchart showing an operation of the mixer 4 when a user operates an ON-button 602 of an input channel 1;

FIG. 14 is a view exemplarily showing an operation panel of the mixer 4 when the calibration mode is relieved;

FIG. 15 is a view showing an operation panel in a modification 1 of the second exemplary embodiment;

FIG. 16 is a flowchart showing an operation of the mixer when a user operates an ALL-ON button 640; and

FIG. 17 is a view showing a block configuration of an input channel i in a modification 2 of the second exemplary embodiment.

### DETAILED DESCRIPTION

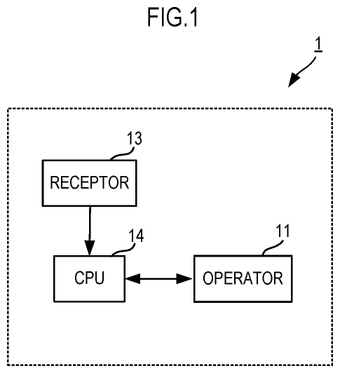

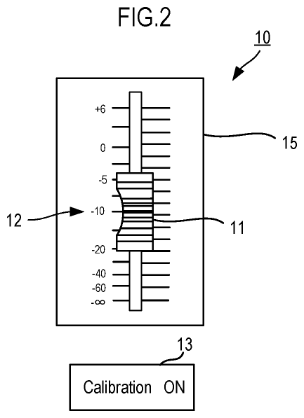

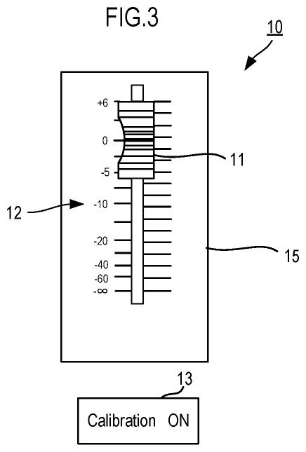

FIG. 1 is a block diagram showing a configuration of a parameter setting device in accordance with a first exemplary embodiment, and FIGS. 2 and 3 are views exemplarily showing an operator of the parameter setting device.

As shown in FIG. 1, the parameter setting device 1 in accordance with the first exemplary embodiment includes, as a hardware configuration, an operator 11, a receptor 13, and a CPU14. The CPU14 is connected to the receptor 13 and the operator 11. Note that, in the parameter setting device 1, the CPU14 is an example of “a controller” in the present invention.

For instance, the parameter setting device 1 includes an operator 10 as a part of a housing. The operator 10 partially constitutes an operation panel of audio equipment as shown in FIG. 2. The operator 10 includes the receptor 13 and a slider 15. The slider 15 includes the operator 11 and a scale 12. The operator 11 is a movable part of the slider 15, i.e., so-called a fader. A motor (not shown) or the like is used to drive the operator 11. The operator 11 can be driven manually or electrically to slide up and down along the scale 12. Note that, the parameter setting device 1 is not limited to the structure including a fader. For instance, the parameter setting device 1 may include a touch panel. In this case, the parameter setting device 1 receives user's instructions through the touch panel.

As shown in FIG. 2, in the operator 10, the scale 12 indicates gain (expressed in units of dB). The scale 12 shows a range from −∞ dB to +6 dB. When the gain is −∞ dB, the parameter setting device 1 is in a silent state. Sound volume (volume) is increased as the gain increases. Accordingly, if a user operates the operator 11, a parameter related to volume will be changed. For instance, by gripping and sliding the operator 11, a user can change the parameter related to volume depending on a position of the operator 11. Note that, the operator 11 is not limited to a fader. For instance, the operator 11 may be a switch or a rotary encoder.

The scale 12 indicates a reference position of the operator 11. In the parameter setting device 1, the reference position is located at a position of 0 dB. Note that, the reference position, which may be set optionally in each parameter setting device, is not limited to a position of 0 dB.

As shown in FIG. 2, the receptor 13 is a switch provided at a part of a housing of the parameter setting device 1, and receives a user's operation. The receptor 13 receives instructions of turning on a calibration mode from a user. The calibration mode is a mode in which the operator 11 is returned back to the reference position to adjust a parameter. In the calibration mode, the operator 11 is apparently moved to the reference position, i.e., a position of 0 dB without changing the actual volume.

When receiving the instructions of turning on a calibration mode from a user, the receptor 13 notifies the CPU14 of the instructions of turning on a calibration mode. Note that, the receptor 13 is not limited to a switch. For instance, the receptor 13 may be a rotary encoder.

The CPU14 reads out a program stored in a memory (not shown), which serves as a storage medium, to execute a predetermined function. Herein, it is assumed that the operator 11 is located at a position of −10 dB before the receptor 13 receives the instructions of turning on a calibration mode, as shown in FIG. 2. In the following, the above-mentioned state will be described.

When receiving the instructions of turning on a calibration mode from the receptor 13, the CPU14 moves the operator 11 to the reference position, i.e., a position of 0 dB, as shown in FIG. 3. At this time, the actual volume remains −10 dB. However, a user can adjust volume from 0 dB as a standard.

To maintain the actual volume, the parameter setting device 1 is provided with a compensation circuit (not shown), for example, at a previous stage of a volume control circuit (not shown). The volume control circuit performs volume control in response to operation of the operator 11. The compensation circuit performs processing to cancel a change caused by the volume control circuit, when a calibration mode is turned on. For instance, if a level of volume is changed by +10 dB in the volume control circuit, the compensation circuit will change the level of volume by −10 dB. Thus, in a calibration mode, the parameter setting device 1 is allowed to move the operator 11 apparently to the reference position, i.e., a position of 0 dB without changing the actual volume. A user can operate the operator 11 from the reference position, i.e., a position of 0 dB, while keeping the current volume, thereby making it easy to understand an amount of the movement intuitively. Therefore, the parameter setting device 1 can improve user's operation feeling in a calibration mode.

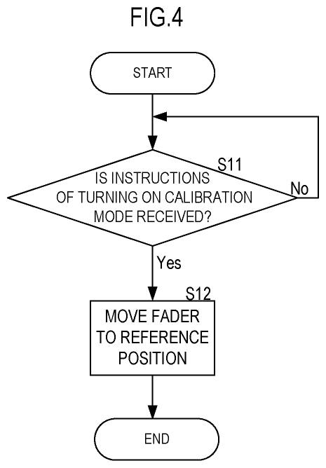

Subsequently, a control method how to move the operator 11 to the reference position through the CPU14, i.e., a parameter setting method will be described with reference to FIGS. 2, 3, and 4. FIG. 4 is a flowchart showing an operation of the parameter setting device in accordance with the first exemplary embodiment.

At the beginning, it is assumed that the operator 11 is located at a position of −10 dB in the scale 12, as shown in FIG. 2. The CPU14 determines whether or not to receive instructions of turning on a calibration mode through the receptor 13 (S11).

When not receiving the instructions of turning on a calibration mode (No at S11), the CPU14 maintains the operator 11 at a position of −10 dB.

When receiving the instructions of turning on a calibration mode (Yes at S11), the CPU14 moves the operator 11 to the reference position (S12). For instance, the CPU14 instructs a driving device, such as a motor (not shown), to move the operator 11 from a position of −10 dB to the reference position (a position of 0 dB) shown in FIG. 3. The driving device (not shown) moves the operator 11 to the reference position.

In this case, the operator 11 is apparently moved to the reference position, i.e., a position of 0 dB, but the actual volume remains −10 dB. Thus, a user can operate the operator 11 from the reference position, i.e., a position of 0 dB, while keeping the current volume, thereby making it easy to understand an amount of the movement intuitively. Therefore, the parameter setting device 1 can improve user's operation feeling in a calibration mode.

Note that, in the example of FIG. 2, resolution of the scale 12 is reduced as the operator 11 goes away from the reference position (0 dB). In other words, the scale 12 has high resolution in the vicinity of the reference position (0 dB). Accordingly, if a calibration mode is turned on, a user can operate the operator 11 in the high resolution area. This enables the parameter setting device 1 to improve user's operation feeling more in a calibration mode. Further, the expression of “resolution is reduced as the operator 11 goes away from the reference position” may means that the resolution changes linearly, non-linearly, or gradually, with respect to a distance from the reference position (0 dB).

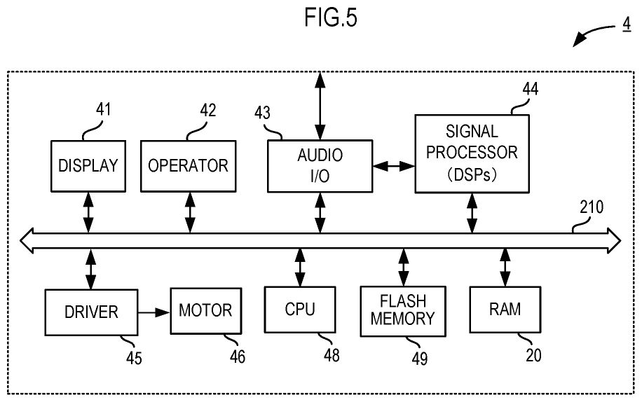

FIG. 5 is a block diagram exemplarily showing a configuration of a mixer (digital mixer) 4 in accordance with a second exemplary embodiment. As shown in FIG. 5, the mixer 4 includes a display 41, an operator 42, an audio I/O43, a signal processor 44, a driver 45, a motor 46, a CPU48, a flash memory 49, and a RAM20. These components, other than the motor 46, are connected to one another through a bus 210. The motor 46 is connected to the driver 45.

The CPU48 controls operation of the mixer 4. The CPU48 reads out a predetermined program stored in the flash memory 49 to execute it, thereby performing various kinds of operations. For instance, the CPU48 performs input and output of a sound signal in the audio I/O43, mixing processing in the signal processor 44, controlling effect processing, changing parameter values related to the above-mentioned matters, and the like. Further, the CPU48 is an example of “the controller” in the present invention.

The CPU48 receives, from the operator 42, instructions of turning on a calibration mode or instructions of relieving the calibration mode. When receiving the instructions of turning on a calibration mode or the instructions of relieving the calibration mode from the operator 42, the CPU48 instructs the driver 45 to drive the motor 46. The driver 45 drives the motor 46 in response to the instructions from the CPU48.

The flash memory 49 stores a parameter value (first value) used for processing an audio signal, information (second value) indicating the current position of an operator in the operator 42, and the like. The information may be stored in the RAM20.

The signal processor 44 is constituted by a plurality of DSPs (Digital Signal Processor) for performing various kinds of signal processing, such as mixing processing and effect processing. The signal processor 44 applies the signal processing, such as mixing processing and effect processing, to a sound signal supplied from the audio I/O43. The signal processor 44 outputs a digital sound signal subjected to the signal processing through the audio I/O43.

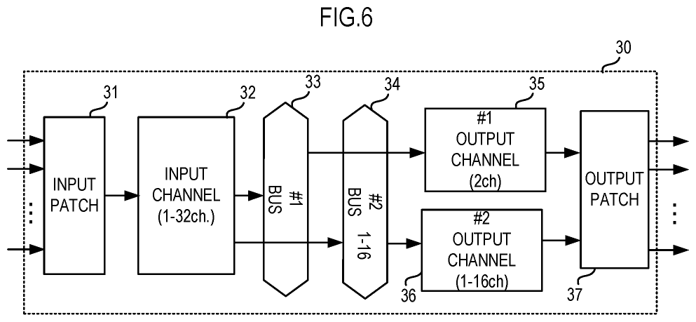

FIG. 6 is a functional block diagram of signal processing 30 performed in the signal processor 44, the audio I/O43, and the CPU48.

As shown in FIG. 6, the signal processing 30 includes blocks such as an input channel 32, a first bus (#1 bus) 33, a second bus (#2 bus) 34, a first output channel (#1 output channel) 35, sixteen second output channels (#2 output channels) 36, and an output patch 37. In the example, the input channel 32 has channels 1 to 32. The #1 bus 33 is a stereo bus, and the #2 bus 34 is constituted by sixteen stereo busses. The first output channel 35 corresponds to the first bus, and the second output channels 36 each correspond to a corresponding one of the sixteen stereo busses in the second bus.

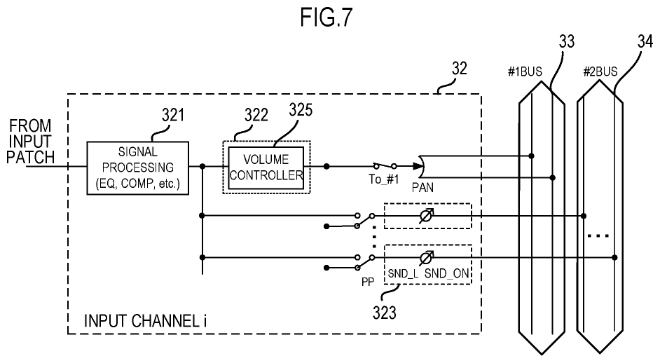

An audio signal is supplied to each input channel i in the input channel 32 from the input patch 31. FIG. 7 is a view showing a block configuration of an input channel i. In the input channel i, the audio signal supplied from the input patch 31 is subjected to linear signal processing, such as an equalizer (EQ), or nonlinear signal processing, such as a compressor (COMP), through a signal processing block 321. The signal processing block 321 is an example of a nonlinear processing that applies nonlinear signal processing, such as a compressor (COMP), to an audio signal. Further, each input channel i in the input channel 32 selectively sends the audio signal, which is subjected to the signal processing, to any one or more of the subsequent buses (#1 bus 33 and #2 bus 34).

For the audio signal sent by the input channel i, a user adjusts a level thereof individually for every bus. For instance, the audio signal, which is to be sent to the #1 bus 33, is subjected to level adjustment in a level adjustment block 322. The level adjustment block 322 includes a volume controller 325. The volume controller 325 performs level adjustment of the audio signal based on a position of the fader, whereby the volume is controlled.

Further, the audio signal to be sent to the #2 bus 34 is subjected to level adjustment in a level adjustment block 323, which is provided at each channel in the #2 bus 34. The level adjustment block 323 includes a send volume (SND_L).

Note that, the audio signal to be sent to the #2 bus 34 can also bypass the level adjustment block 322, when a selector (PP in the figure) is used. Further, on an output side of the level adjustment block 322, a panning block (PAN) is provided between an output side switch (To_#1) and a two-channel.

Audio signals supplied to the #1 bus 33 and the #2 bus 34 each are mixed and outputted to a corresponding one of a #1 output channel 35 and a #2 output channel 36. The audio signals inputted to each channel in the #1 output channel 35 and the #2 output channel 36 are subjected to signal processing such as an equalizer or a compressor. The audio signals subjected to the signal processing are supplied to the audio I/O43.

Through user's operation, i.e., by operating a touch screen, a fader, a knob, a button, or the like provided on an operation panel of the mixer 4, the level value in the level adjustment block 322, the level value in the level adjustment block 323, and each parameter value in the signal processing block 321 are changed.

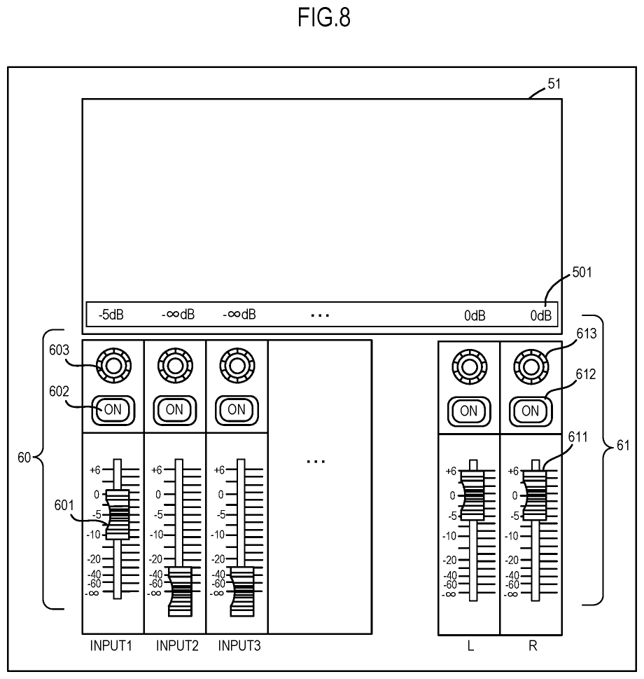

FIG. 8 is a view exemplarily showing an operation panel of the mixer 4. As shown in FIG. 8, a touch screen 51, a channel strip 60, an LR channel strip 61, and the like are provided on the operation panel of the mixer 4. These components correspond to the operator 42 shown in FIG. 5.

The touch screen 51 is a display 41 on which a touch panel is laminated. Herein, the touch panel corresponds to one embodiment of the operator 42. The touch screen 51 displays a GUI (graphical user interface) screen for receiving user's operation. In the example, the touch screen 51 displays the current fader values on a current-value display area 501 located in a lower part of the touch screen 51. In a left-hand side block of the current-value display area 501, the current fader value (CF(i)) for each channel is displayed. In a right-hand side block of the current-value display area 501, the current fader values (DF (g)) for an L channel and an R channel are displayed. Note that, a dedicated display for displaying the current-value display area 501 may be provided apart from the touch screen 51.

The channel strip 60 and the LR channel strip 61 are areas in which a plurality of operators, each being directed vertically and receiving an operation for each channel, are arranged side by side. In the figure, a fader 601, an ON-button 602, and a knob 603 are disposed for every channel in the channel strip 60. Further, a fader 611, an ON-button 612, and a knob 603 are disposed for every channel in the LR channel strip 61. In addition to the button and the knob shown in FIG. 8, the optional number of knobs and buttons may be provided on the operation panel, for example. Note that, the fader 601 and the fader 611 each are an example of “the operator” in the present invention. Further, the ON-button 602 and the ON-button 612 each are an example of “the receptor” in the present invention, and the knob 603 and the knob 613 each are an example of “the operator” in the present invention. In the example, the knob 603 and the knob 613 are knobs for adjusting the send volume (SND_L).

In the example, input channels (input channel 1, input channel 2, input channel 3, and so on from the left-hand side in this order) each are assigned to a corresponding one of a plurality of strips (e.g., eight strips) disposed on the left-hand side of the operation panel as the channel strip 60. The L channel and the R channel each are assigned to a corresponding one of two strips disposed on the right-hand side of the operation panel as the LR channel strip 61.

The flash memory 49 stores a volume (Vol) value (first value) of the volume controller 325, which is used for processing an audio signal, and a value (second value) indicating the current position of the fader 601 or the fader 611 in the operator 42.

In the example, the ON-button 602 or the ON-button 612 is provided one by one for each channel. The ON-button 602 or the ON-button 612 is switched on and off by pushing operation thereof. For instance, the ON-button 602 or the ON-button 612 may be lit on when being turned on. Further, when the ON-button 602 or the ON-button 612 is turned on, the fader 601 or the fader 611 corresponding thereto may be lit on. This enables a user to understand the current state (whether the mixer 4 is in a calibration mode or not) of the mixer 4 more easily. Note that, instead of the ON-button 602 or the ON-button 612, the channel strip 60 and the LR channel strip 61 each may include a pair of buttons, which is constituted by an ON-button and an OFF-button, for every channel.

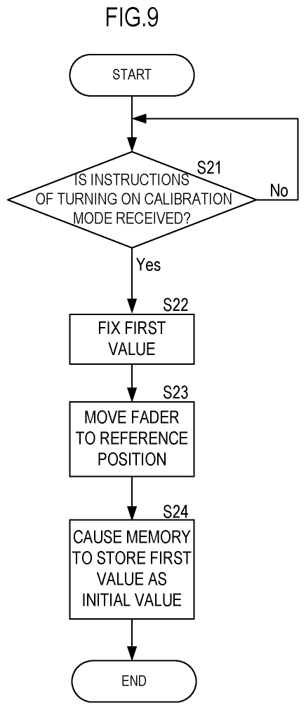

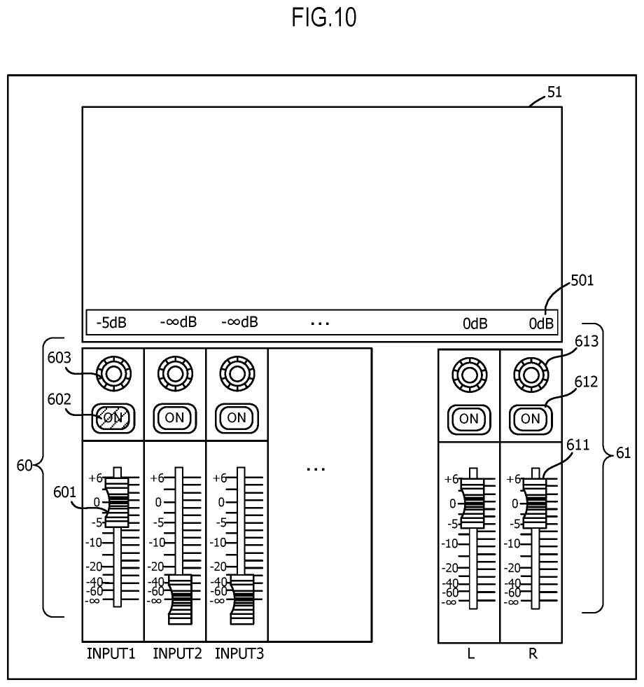

FIG. 9 is a flowchart showing an operation of the mixer 4 when a user operates the ON-button 602 of the input channel 1. FIG. 10 is a view exemplarily showing an operation panel of the mixer 4 displayed when a calibration mode is turned on.

At the beginning, it is assumed that the fader 601 is located at a position of −5 dB, as shown by the input channel 1 in FIG. 8. The CPU48 displays, in the current-value display area 501, the first value (−5 dB) indicating the current position of the fader 601 and used for processing an audio signal. First, the CPU48 determines whether or not to receive instructions of turning on a calibration mode through the ON-button 602 (S21).

When not receiving the instructions of turning on a calibration mode (No at S21), the CPU48 maintains the fader 601 at a position of −5 dB.

When receiving the instructions of turning on a calibration mode through pushing operation of the ON-button 602 (Yes at S21), the CPU48 fixes the first value (−5 dB) indicating the current position of the fader 601 (S22). Accordingly, the first value displayed in the current-value display area 501 does not change from −5 dB.

Subsequently, the CPU48 instructs the driver 45 to drive the motor 46, thereby moving the fader 601 to the reference position (0 dB), as shown in FIG. 10 (S23). In other words, the second value is changed to 0 dB. The CPU48 instructs the driver 45 to drive the motor 46 such that the fader 601 is moved by only +5 dB. The driver 45 receives the instructions from the CPU48, and moves the fader 601 to a position of 0 dB.

In this case, although the second value, serving as an apparent position of the fader 601, is changed to 0 dB corresponding to the reference position, the first value related to actual volume is fixed at −5 dB, i.e., the initial value. Thus, a user can operate the fader 601 from 0 dB, i.e., the reference position, while keeping the current volume. This enables a user to understand an amount of the movement intuitively. Therefore, the mixer 4 can improve user's operation feeling in a calibration mode.

When the fader 601 is moved to the reference position (0 dB), the CPU48 causes the flash memory 49 to store the first value, i.e., −5 dB as an initial value (S24). Thus, the CPU48 can read out the initial value, rather than the apparent position, from the flash memory 49. Herein, the initial value indicates a value related to actual volume in the calibration mode.

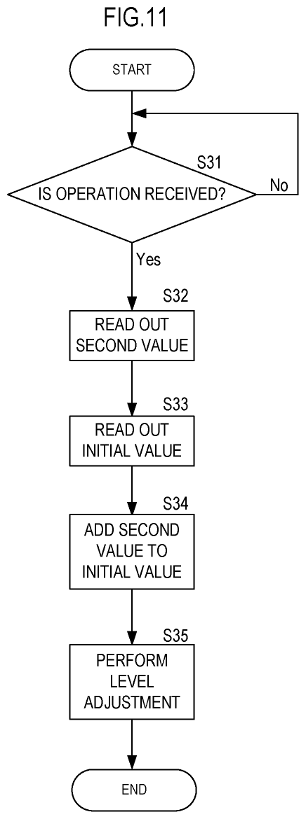

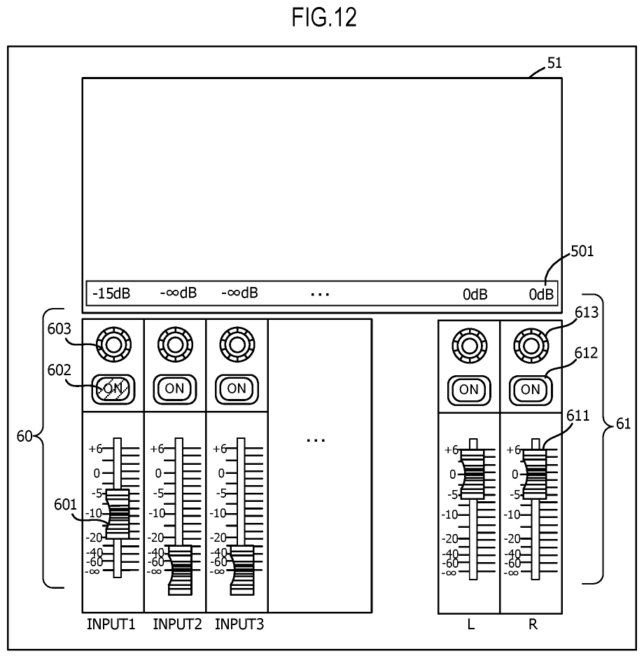

FIG. 11 is a flowchart showing an operation of the mixer 4 when a user operates the fader 601 of the input channel 1. FIG. 12 is a view exemplarily showing an operation panel of the mixer 4 displayed when a calibration mode is turned on.

For instance, the case where a user moves the fader 601 from the reference position (0 dB) to a position of −10 dB in a calibration mode will be described. At the beginning, it is assumed that the fader 601 is located at a position of 0 dB, as shown in FIG. 10. In other words, the second value serving as an apparent position of the fader 601 is 0 dB. At this time, the first value related to actual volume remains −5 dB, i.e., the initial value. First, the CPU48 determines whether or not the fader 601 receives any operation from a user (S31).

When the fader 601 receives no operation from a user (No at S31), the CPU48 maintains the fader 601 at a position of 0 dB.

When the fader 601 receives any operation from a user (Yes at S31), the CPU48 reads out the second value indicating the current position of fader 601 (S32). For instance, the case where a user moves the fader 601 from a position of 0 dB to a position of −10 dB, as shown in FIG. 12, will be described. In this case, the second value, which indicates an apparent position of the fader 601, is −10 dB. The CPU48 reads out the second value, i.e., −10 dB.

The CPU48 reads out the initial value (−5 dB), which is the first value, from the flash memory 49 (S33). Subsequently, the CPU48 adds the initial value (−5 dB) to the second value (−10 dB) (S34). As a result, the first value used for processing an audio signal becomes −15 dB, which is obtained by adding −10 dB to −5 dB. The CPU48 displays −15 dB in the current-value display area 501 as a new first value used for processing an audio signal. The CPU48 causes the volume controller 325 to adjust a level of an audio signal based on the obtained value, i.e., −15 dB as the first value.

In this case, although the second value, which is an apparent position of the fader 601, is changed to −10 dB, the first value used for actual processing in the volume controller 325 is −15 dB. Thus, by checking the second value serving as the reference position, a user can verify how long the fader 601 is moved from a position of 0 dB. This enables a user to understand an amount of the movement intuitively. Further, by checking the current-value display area 501, a user can recognize a new first value used for actually processing an audio signal in the volume controller 325. Therefore, the mixer 4 can improve user's operation feeling in a calibration mode.

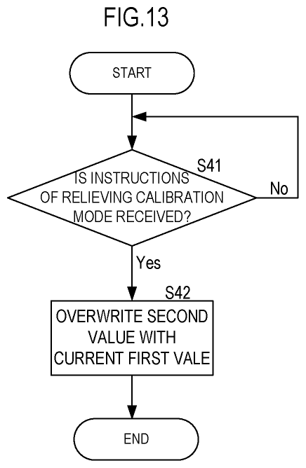

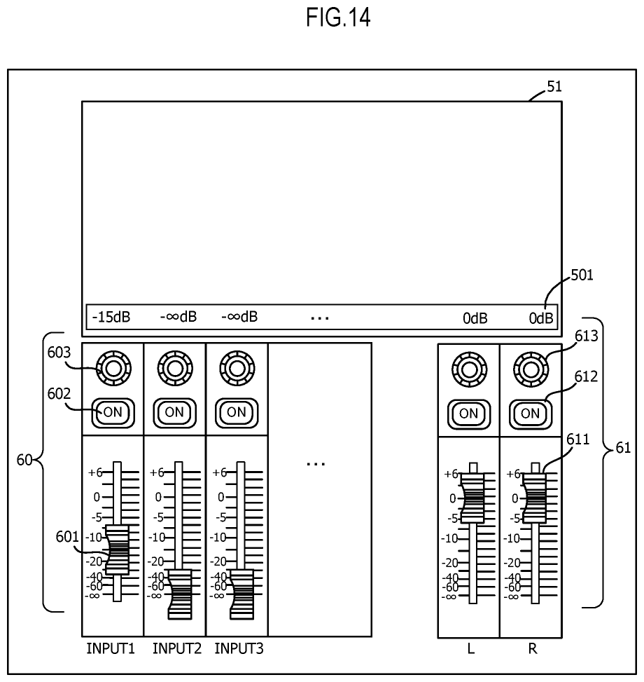

FIG. 13 is a flowchart showing an operation of the mixer 4 when a user operates the ON-button 602 of the input channel 1. FIG. 14 is a view exemplarily showing an operation panel of the mixer 4 displayed when the calibration mode is relieved. Herein, the case where the calibration mode is relieved through operation of the ON-button 602 will be described.

At the beginning, it is assumed that the fader 601 is located at a position of −10 dB, as shown by the input channel 1 in FIG. 12. Accordingly, the second value serving as an apparent position of the fader 601 is −10 dB. Further, at this time, the first value used for processing an audio signal is −15 dB, which is displayed in the current-value display area 501. First, the CPU48 determines whether or not to receive instructions of relieving the calibration mode through the ON-button 602 (S41).

When not receiving the instructions of relieving the calibration mode (No at S41), the CPU48 maintains the fader 601 at a position of −10 dB.

When receiving the instructions of relieving the calibration mode through pushing operation of the ON-button 602 (Yes at S41), the CPU48 overwrite the second value (−10 dB), which serves as an apparent position of the fader 601, with the first value (−15 dB) used for processing an audio signal (S42). In other words, the CPU48 changes the second value to the first value used for actually processing an audio signal. Further, the CPU48 instructs the driver 45 to drive the motor 46 such that the fader 601 is moved to the first value, i.e., a position of −15 dB, as shown in FIG. 14.

In this case, the second value serving as an apparent position of the fader 601 is −15 dB, i.e., the same as the first value used for actually processing an audio signal in the volume controller 325. Thus, only by operating the ON-button 602 to relieve the calibration mode, a user can move the fader 601 to a position related to the first value used for actually processing an audio signal in the volume control part 325.

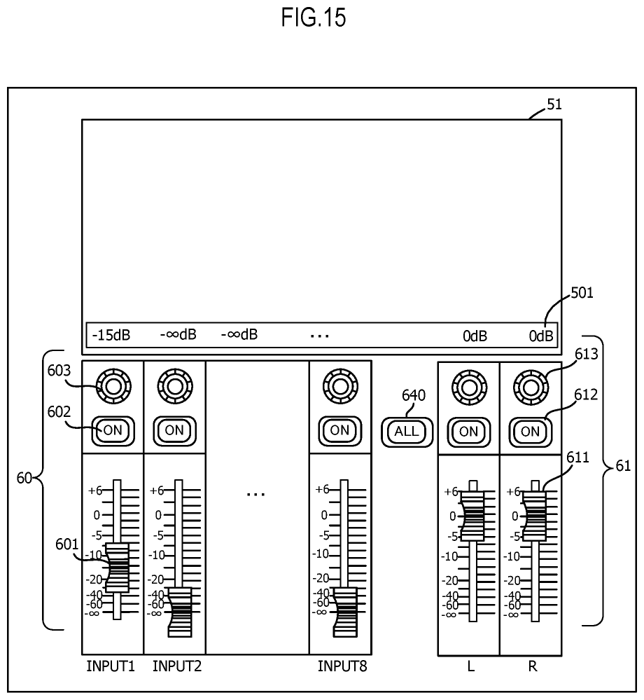

FIG. 15 is a view showing an operation panel of the mixer (digital mixer) in accordance with a modification 1 of the second exemplary embodiment. In the modification 1 of the second exemplary embodiment, only a part different from the mixer 4 in accordance with the second exemplary embodiment will be described, and the description of the other parts is omitted.

As shown in FIG. 15, in addition to the ON-button 602 and the ON-button 612, an ALL ON-button 640 is provided on an operation panel of the mixer in accordance with the modification 1 of the second exemplary embodiment.

The ALL ON-button 640 is switched on and off through pushing operation thereof. Herein, the ALL ON-button 640 switches on and off the ON-buttons 602 and the ON-buttons 612 related to all channels in the channel strip 60 and the LR channel strip 61, collectively.

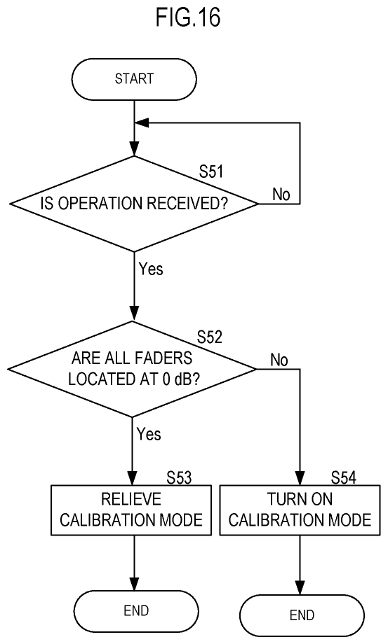

FIG. 16 is a flowchart showing an operation of the mixer when a user operates the ALL ON-button 640.

First, the CPU48 determines whether the ALL ON-button 640 is operated or not (S51). When the ALL ON-button 640 is not operated (No at S51), the CPU48 maintains positions of the faders 601 and the faders 611 related to all channels in the channel strip 60 and the LR channel strip 61.

When the ALL ON-button 640 is pushed, i.e., the ALL ON-button 640 is operated (Yes at S51), the CPU48 determines whether all the faders 601 and all the faders 611 are located at the reference position (0 dB) or not (S52).

When all the faders 601 and all the faders 611 are located at the reference position (0 dB) (Yes at S52), the CPU48 relieves the calibration mode (S53).

For instance, like the faders 611 in the LR channel strip 61 shown in FIGS. 8, 10, 12, 14 and 15, when all the faders 601 and all the faders 611 are aligned at a position of 0 dB, the second values indicating apparent positions of all the faders 601 and all the faders 611 are 0 dB. The CPU48 reads out the second values related to all the faders 601 and all the faders 611. If the second values related to all the fader 601 and all the faders 611 are 0 dB, the CPU48 will determine that the mixer is in a calibration mode. Therefore, the CPU48 is allowed to relieve the calibration mode of the mixer.

When all the faders 601 and all the faders 611 are not located at the reference position (0 dB) (No at S52), the CPU48 turns on a calibration mode (S54).

For instance, the case as shown in FIG. 15 is assumed. The case as shown in FIG. 15 shows that at least one of the second values indicating apparent positions of the faders 601 in the input channel 1, the input channel 2, and the input channel 8 is not 0 dB. If the second values, which are read out through all the faders 601 and all the faders 611, include non-zero values, the CPU48 will determine that the mixer is not in a calibration mode. Accordingly, the CPU48 is allowed to turn on a calibration mode, i.e., turn the mixer into the calibration mode.

In this way, the ALL ON-button 640 can switch on and off a calibration mode collectively, with respect to all the faders 601 and all the faders 611. Note that, the ALL ON-button 640 switches on and off a calibration mode collectively with respect to all the fader 601 and all the faders 611, but not limited to this. The ALL ON-button 640 may switch on and off a calibration mode collectively with respect to all the faders 601 in the channel strip 60, or with respect to all the faders 611 in the LR channel strip 61. Further, regardless of the current positions of all the faders 601 and all the faders 611, a calibration mode may be switched on and off collectively through operation of the ALL ON-button 640.

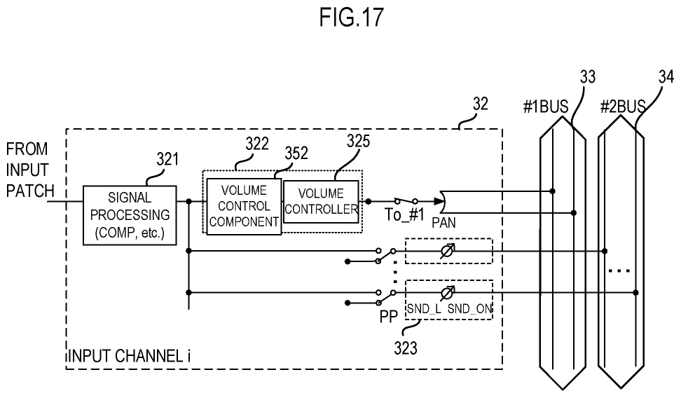

FIG. 17 is a view showing a block configuration of an input channel i in accordance with a modification 2 of the second exemplary embodiment. In the modification 2 of the second exemplary embodiment, only a part different from the mixer 4 in accordance with the second exemplary embodiment will be described, and the description of the other parts is omitted.

As shown in FIG. 17, the block configuration of the input channel i in accordance with the modification 2 of the second exemplary embodiment further includes a volume control component 352. The volume control component 352 is disposed at a subsequent stage of the signal processing block 321 and at a previous stage of the volume controller 325. The signal processing block 321 is an example of “the nonlinear processing.”

Each input channel i in the input channel 32 applies nonlinear signal processing, such as a compressor (COMP), to an audio signal in the signal processing block 321. The audio signal to be sent to the #1 bus 33 through input channel i is subjected to level adjustment for every bus in the level adjustment block 322.

In a calibration mode, the volume control component 352 controls volume such that a level of the audio signal in the volume controller 325 is compensated by an amount of movement from a reference value (0 dB) of the fader. For instance, when receiving instructions of turning on a calibration mode through the ON-button 602, CPU48 moves the fader 601 from a position of −5 dB to the reference position, i.e., a position of 0 dB, as shown in FIGS. 8 and 10. In this case, the volume control part 325 performs such processing that a level of an audio signal is changed by +5 dB. The volume control component 352 perform such processing that the level of the audio signal is changed by −5 dB. Consequently, the actual volume is maintained at −5 dB.

In this case, the volume control component 352 is disposed at the previous stage of the volume control part 325 and at the subsequent stage of the signal processing block 321, thereby being unaffected by any processing in the signal processing block 321. Further, it is preferred that the volume control component 352 is provided just before the volume controller 325. Thus, no other audio signals are processed between the volume control component 352 and the volume controller 325, so that a level of the audio signal in the volume control component 352 is compensated by an amount of movement from a reference value of the fader, more correctly.

Note that, in the above-mentioned example, a physical fader provided on the operation panel of the mixer is employed, but the physical fader is only an example. As the fader, a fader displayed on a touch screen may be employed, for example. In this case, the fader receives an operation from a user through the GUI. In the example, information (second value) indicating the current position of a fader and a parameter value (first value) used for processing an audio signal may be displayed in different manners from each other. For instance, a fader indicating the first value may be displayed by a dashed line, whereas a fader indicating the second value may be displayed by a solid line. Alternatively, a fader indicating the first value may be displayed more darkly than a fader indicating the second value. Note that, even when a fader is displayed on a touch screen, the second value may be displayed as a numerical value. Furthermore, the first value may be displayed as a numerical value.

Note that, in the above-mentioned example, faders for the input channel and the LR channel, each adjusting volume as an operator, are employed, but the faders for the input channel the LR channel are only an example. As the fader, a fader for an output channel, a DCA (Digital Controlled Amplifier), or the like may be employed, for example.

In addition, the above explanations of the preferred embodiments and modification examples are nothing more than illustrative in any respect, and are not restrictive. Scope of the present invention is indicated by claims rather than the above embodiments. Further, the scope of the present invention includes all modifications within the scopes of the claims and within the meanings and scopes of equivalents.

What is claimed is:

1. A parameter setting device comprising:
an operator that receives parameter changing operation from a user;
a scale that indicates a reference position of the operator;
a receptor that receives instructions of turning on a calibration mode; and
a controller that moves the operator to the reference position, when receiving the instructions of turning on the calibration mode.

2. The parameter setting device according to claim 1, further comprising
a memory that stores a first value used for processing an audio signal, and a second value indicating a current position of the operator,
wherein
the controller changes the second value to a value corresponding to the reference position, when receiving the instructions of turning on the calibration mode.

3. The parameter setting device according to claim 2, wherein
the controller changes the second value to the first value, when receiving instructions of relieving the calibration mode.

4. The parameter setting device according to claim 1, wherein
resolution of the scale is reduced as the operator goes away from the reference position.

5. The parameter setting device according to claim 1, further comprising a plurality of the operators,
wherein
the controller moves the plurality of the operators to the reference position collectively, when receiving the instructions of turning on the calibration mode.

6. The parameter setting device according to claim 5, wherein
when receiving the instructions of turning on the calibration mode in a state where the plurality of the operators include an operator whose current position is not the reference position, the controller moves the operator, which is located at a position other than the reference position, to the reference position.

7. The parameter setting device according to claim 1, wherein
a plurality of the receptors each correspond to a channel of an audio signal and receive operation of turning on and off the calibration mode for every channel.

8. The parameter setting device according to claim 1, further comprising
a signal processor that applies signal processing to an audio signal, wherein
the signal processor performs:
nonlinear processing in which nonlinear processing is applied to the audio signal;
first volume-control processing in which volume is controlled based on a current value of the operator; and
second volume-control processing in which, after the nonlinear processing and before the first volume-control processing, volume is controlled such that the volume controlled in the first volume-control processing is compensated by an amount of movement from a reference value of the operator.

9. A parameter setting method comprising:
receiving instructions of turning on a calibration mode; and
moving an operator, which receives operation from a user, to a reference position, when the instructions of turning on the calibration mode are received.

10. The parameter setting method according to claim 9, further comprising:
storing a first value used for processing an audio signal, and a second value indicating a current position of the operator; and
changing the second value to a value corresponding to the reference position, when the instructions of turning on the calibration mode are received.

11. The parameter setting method according to claim 10, further comprising
changing the second value to the first value, when instructions of relieving the calibration mode are received.

12. The parameter setting method according to claim 9, further comprising
moving a plurality of the operators to the reference position collectively, when the instructions of turning on the calibration mode are received.

13. The parameter setting method according to claim 12, further comprising
when the instructions of turning on the calibration mode are received in a state where the plurality of the operators include an operator whose current position is not the reference position, moving the operator, which is located at a position other than the reference position, to the reference position.

14. The parameter setting method according to claim 9, further comprising
receiving operation of turning on and off the calibration mode for every channel.

15. The parameter setting method according to claim 9, further comprising
performing:
nonlinear processing in which nonlinear processing is applied to an audio signal;
first volume-control processing in which volume is controlled based on a current value of the operator; and
second volume-control processing in which, after the nonlinear processing and before the first volume-control processing, volume is controlled such that the volume controlled in the first volume-control processing is compensated by an amount of movement from a reference value of the operator.
